(19) United States
(12) Patent Application Publication
(10) Pub. No.: US 2021/0153394 A1
(43) Pub. Date: May 20, 2021

(54) COOLING ARRANGEMENT FOR ELECTRICAL COMPONENTS, CONVERTER WITH A COOLING ARRANGEMENT, AND AIRCRAFT HAVING A CONVERTER

(71) Applicant: SIEMENS AKTIENGESELLSCHAFT, München (DE)

(72) Inventors: Gerhard Mitic, München (DE); Stanley Buchert, Herzogenaurach (DE); Uwe Waltrich, Erlangen (DE); Antonio Zangaro, Schwanstetten (DE)

(21) Appl. No.: 17/048,641

(22) PCT Filed: Apr. 9, 2019
(86) PCT No.: PCT/EP2019/058883

§ 371 Date: Oct. 19, 2020

(30) Foreign Application Priority Data
Apr. 19, 2018 (DE) 10 2018 206 020.7

(51) Int. Cl. H05K 7/20; H01L 25/07; H01L 23/367; H01L 23/373; H01L 23/427; H02K 11/33; B64D 27/24; B64C 11/00; B64D 33/08; F28D 15/02; H05K 1/18; H05K 1/02

(52) U.S. Cl. CPC H05K 7/20936; B64D 2027/026; H01L 23/3672; H01L 23/3735; H01L 23/427; H02K 11/33; B64D 27/24; B64C 11/00; B64D 33/08; F28D 15/0233; H05K 1/181; H05K 7/209; H05K 1/0204; B64D 2221/00; H01L 25/072

(57) ABSTRACT

The disclosure specifies an arrangement including a circuit carrier board on which is mounted at least one electrical/electronic component. At least one heat pipe is formed in the circuit carrier board. The disclosure also specifies a power converter including the arrangement, and an aircraft including a power converter.

The present patent document is a § 371 nationalization of PCT Application Serial No. PCT/EP2019/058883, filed Apr. 9, 2019, designating the United States, which is hereby incorporated by reference, and this patent document also claims the benefit of German Patent Application No. 10 2018 206 020.7, filed Apr. 19, 2018, which is also hereby incorporated by reference.

### TECHNICAL FIELD

The disclosure relates to an arrangement including an electrical/electronic component, which is mounted on a circuit carrier board. The disclosure also relates to a power converter including the arrangement, and to an aircraft including an electric or hybrid-electric propulsion system.

### BACKGROUND

The maximum permitted semiconductor temperatures may limit the approved area of use and the power density of electrical and/or electronic components such as power modules, for instance, in particular for converters in electric and hybrid-electric aviation. The service life of power modules is primarily defined by the service life of the chip attachment. The semiconductor temperature and the service life are heavily dependent on the thermal resistance of the semiconductor with respect to the cooling medium.

The thermal resistance (e.g., from the semiconductor to the surroundings) depends on: the heat transfer coefficient between a cooling unit and the surroundings; the temperature difference between the external surface of the cooling unit and the surroundings; and the size of the cooling surface.

Because the waste power to be dissipated is produced by power modules only at specific points in the semiconductor, lateral thermal conduction (what is known as “heat spreading”) in the power module and in the cooling unit also plays an important role. A large temperature difference with respect to the surroundings exists over the entire cooling surface to achieve a low thermal resistance.

A high temperature difference over as large a cooling surface as possible is the aim in particular for air-cooled power electronic systems that have a low heat transfer coefficient. This requires very high lateral thermal conduction through layers close to the heat source (e.g., semiconductor chip) that are good thermal conductors.

Lateral thermal conduction from known power modules may take place through copper metallizations of the ceramic insulating substrates used in the circuit carrier board. The metallizations have a maximum lateral thermal conduction of less than 400 W/mK, however. In addition, the available layer thicknesses of the copper metallizations of such substrates are less than 1 mm, again limiting the lateral thermal conduction.

This necessitates using large heat sinks having extremely long and weight-intensive cooling fins. This leads to the following problems: high costs and high level of technical complexity; oversizing due to identical modules being connected in parallel; power modules able to operate only with off-design performance; and high weight and large volume.

Laid-open specification DE 3625979 A1 discloses forming a heat pipe in a heat sink. The heat pipe achieves more uniform heat distribution in the heat sink. German utility model DE 89 15 913 U1 also discloses using heat pipes to cool a power semiconductor.

A heat pipe is a heat exchanger that uses the heat of vaporization of a medium to make a high heat-flux density possible, e.g., large amounts of heat may be transported over a small cross-sectional area. The two-phase thermosyphon is a distinct form of heat pipe design. The basic operating principle is the same for both designs, with the difference lying in the transport of the working medium, although this may be achieved by passive methods, devices, or systems, e.g., without assistance, for instance, from a circulating pump.

The term “heat pipe” is used generically below.

A power converter which uses an AC voltage or DC voltage to produce an AC voltage, the frequency and amplitude of which are varied, is referred to as a converter, also called an inverter. Converters may be designed as AC/DC-DC/AC converters or DC/AC converters, wherein an AC output voltage is generated from an AC input voltage or a DC input voltage via a DC link and switched semiconductors.

### SUMMARY

The object of the disclosure is to specify a solution for providing improved cooling of electrical and/or electronic components, in particular of power semiconductors in electric or hybrid-electric aviation.

The scope of the present disclosure is defined solely by the appended claims and is not affected to any degree by the statements within this summary. The present embodiments may obviate one or more of the drawbacks or limitations in the related art.

The greater the lateral thermal conduction from a heat source, (e.g., from a power semiconductor), the better the utilization of the available cooling surface of a heat sink and the smaller, cheaper, and lighter the design may be of the heat sink.

Therefore, according to the disclosure, planar and/or three-dimensional arrangements of heat pipes (HP for short) or oscillating/pulsating heat pipes (OHP for short) are used as a lateral heat-conducting layer in the circuit carrier board, for instance, of the power modules.

The greater lateral thermal conduction (e.g., >1000 W/mK) of the planar or three-dimensional heat pipe compared with copper layers or the like is achieved by a phase transition of the working fluid in the heat pipe. By virtue of the heat pipes having a three-dimensional design or three-dimensional shape, these heat pipes may be used simultaneously both for heat transfer and for heat exchange with the surroundings.

The disclosure provides the following advantages. For example, for one advantage, if the heat pipe is the heat sink, this results in a homogeneous temperature difference between the heat-sink outer skin and the surroundings over the entire cooling surface. This increases the heat-sink efficiency, allowing a reduction in the volume and weight of the heat sink.

In another advantage, thick copper layers may be avoided in the insulating substrates (e.g., circuit carrier board), thereby reducing the weight of the power module.

In another advantage, the thermal resistance (e.g., semiconductor to surroundings) is improved. This increases the service life of the chip attachment by reducing the thermal cycling stresses for a constant power capability of the power electronic system.

The disclosure relates to an arrangement including a circuit carrier board on which is mounted at least one electrical/electronic component. At least one heat pipe is formed in the circuit carrier board.

The disclosure provides the advantage that the two-phase heat transport of the heat pipe is used to spread the heat over large areas. This increases the effective thermal conductivity by orders of magnitude, thereby providing the improved heat spreading.

In a development, the heat pipe may be arranged predominantly beneath the electrical/electronic component. The waste heat may thereby be removed in a highly targeted manner.

In a further embodiment, the heat pipe may be a pulsating heat pipe. This exhibits improved cooling compared with standard heat pipes.

In a further embodiment, the electrical/electronic component may be a power semiconductor.

In a further embodiment, the heat pipe may have a meandering course or a concentrically wound course.

In a further embodiment, the heat pipe may be formed in a ceramic substrate or a circuit trace layer of the circuit carrier board.

The arrangement may include a metal heat sink, which is arranged under the circuit carrier board and connected thereto in a thermally conductive manner.

In a further configuration, there may be an additional heat pipe formed in the heat sink.

In a further embodiment, the circuit carrier board may have, in the direction facing the heat sink, a partially open structure, and the heat sink may have, in the direction facing the circuit carrier board, a partially open, additional structure, with both structures designed and joined so as to form the heat pipe.

In addition, the circuit carrier board may be a direct copper bonding (DCB) substrate board.

The disclosure also relates to a converter, (e.g., a power converter), including an arrangement as disclosed herein.

The disclosure also relates to an aircraft including a power converter and an electric motor as an electric aircraft propulsion system, wherein the electric motor is supplied with electrical power by the converter.

In one embodiment, the aircraft is an airplane, and the electric motor drives a propeller.

### BRIEF DESCRIPTION OF THE DRAWINGS

Further special features and advantages of the disclosure will become clear from the following explanations of an exemplary embodiment with reference to schematic drawings, in which:

FIG. 1 depicts a sectional view through an arrangement according to the prior art.

FIG. 2 depicts a sectional view through an arrangement including a heat pipe in the circuit carrier board, according to an embodiment.

FIG. 3 depicts a sectional view through a further arrangement including a heat pipe in the circuit carrier board, according to an embodiment.

FIG. 4 depicts a view of the course of the channels of a heat pipe, according to an embodiment.

FIG. 5 depicts a view of the course of the channels of a further heat pipe, according to an embodiment.

FIG. 6 depicts a sectional view through an arrangement including a heat pipe formed in the circuit trace layer of the circuit carrier board, according to an embodiment.

FIG. 7 depicts a sectional view through an arrangement including a heat pipe formed in the circuit trace layer and in the heat sink, according to an embodiment.

FIG. 8 depicts a sectional view through an arrangement including a heat pipe formed in a ceramic substrate of the circuit carrier board and in the heat sink, according to an embodiment.

FIG. 9 depicts a block diagram of a converter including an arrangement including a heat pipe, according to an embodiment.

FIG. 10 depicts an aircraft including an electric propulsion system, according to an embodiment.

### DETAILED DESCRIPTION

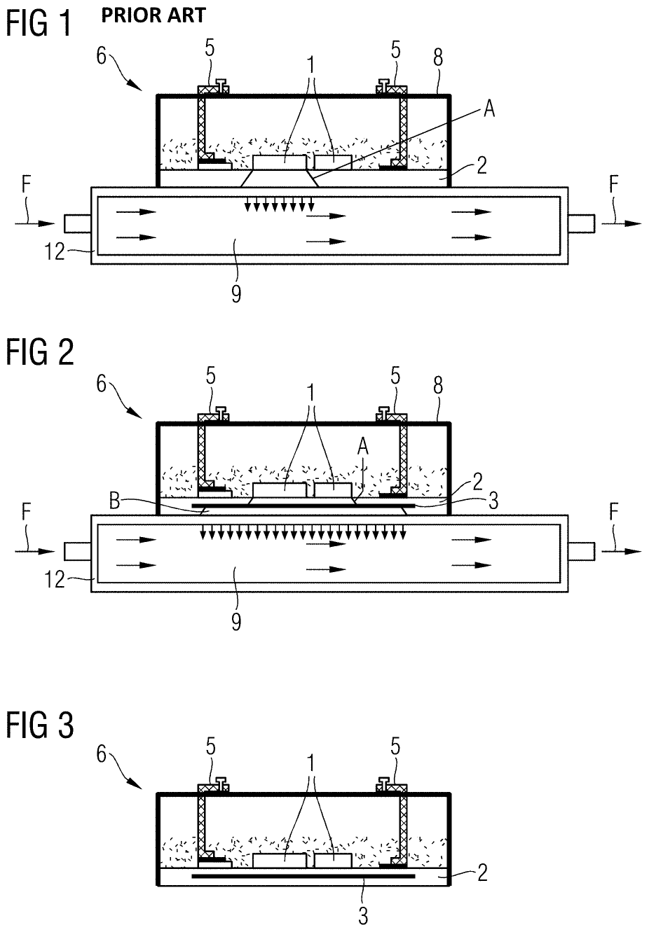

FIG. 1 depicts a sectional view through a power module 6, which sits on a heat sink 12, according to a generic arrangement. The power module 6 includes a circuit carrier board 2, on which are mounted the power semiconductors 1. The power module 6 is sealed by a housing 8, through which the electrical power may be supplied and/or removed by the load current contacts 5. The heat sink 12 is cooled by water 9, which flows through the heat sink 12 in the direction F.

The region A shows the heat transfer from the power semiconductors 1 to the heat sink 12. This generically exhibits only low heat spreading.

FIG. 2 depicts a sectional view through a power module 6, which sits on a heat sink 12, but unlike FIG. 1 additionally includes a heat pipe 3. The power module 6 includes a circuit carrier board 2, on which are mounted the power semiconductors 1. The power module 6 is sealed by a housing 8, through which the electrical power may be supplied and/or removed by the load current contacts 5. The heat sink 12 is cooled by water 9, which flows through the heat sink 12 in the direction F.

The region A shows the heat transfer from the power semiconductors 1 to the heat sink 12. This exhibits only low heat spreading. The heat pipe 3 formed however in the circuit carrier board 2 results in an increase in the heat spreading, as represented by the region B. Thus, by the heat pipe 3, the heat emitted by the power semiconductors 1 may be distributed over a larger area, thereby significantly improving the cooling of the power semiconductors 1.

FIG. 3 depicts a sectional view of an arrangement that is similar to the arrangement of FIG. 2 only without a heat sink. It shows a power module 6 including a heat pipe 3. The power module 6 includes a circuit carrier board 2, on which are mounted the power semiconductors 1. The power module 6 is sealed by a housing 8, through which the electrical power may be supplied and/or removed by the load current contacts 5.

The heat pipe 3 achieves greater heat spreading of the waste heat produced by the power semiconductors 1. The heat pipe 3 may also be in the form of a pulsating (e.g., oscillating) heat pipe as known from the prior art. The heat pipe 3 is advantageously formed predominantly in the region beneath the power semiconductors 1.

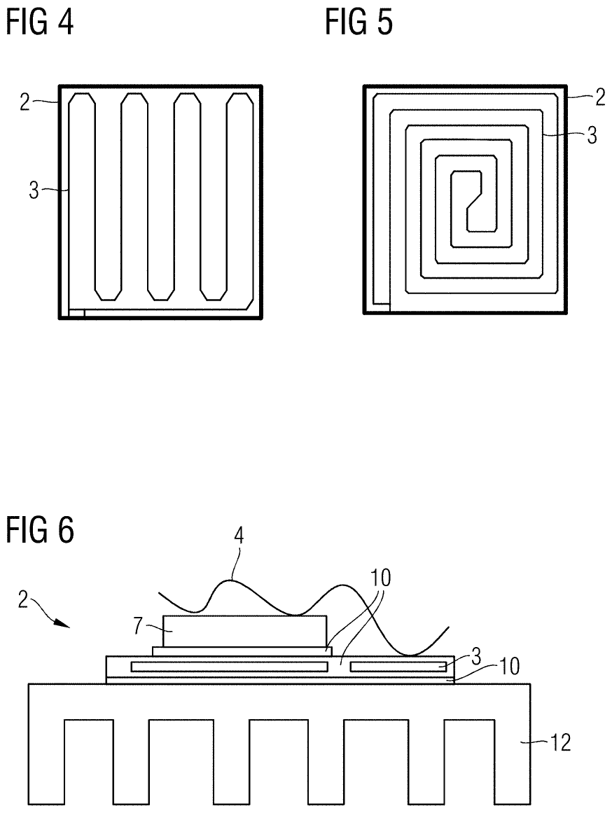

FIG. 4 and FIG. 5 depict possible courses of the heat pipe 3 in the circuit carrier board 2. FIG. 4 depicts an approximately meandering course, whereas FIG. 5 depicts an approximately concentric, approximately circular, course.

FIG. 6 depicts a sectional view through a heat emitting electrical/electronic component 7, which is mounted on a circuit carrier board 2. The component 7 is electrically connected to a bonding wire 4. The heat pipe 3 is formed in the circuit carrier board 2. The heat pipe 3 may be formed in a ceramic substrate 13 or in an electrical circuit trace layer 11 of the circuit carrier board 2. The heat pipe 3 is advantageously a pulsating heat pipe. The circuit carrier board 2 sits on a heat sink 12.

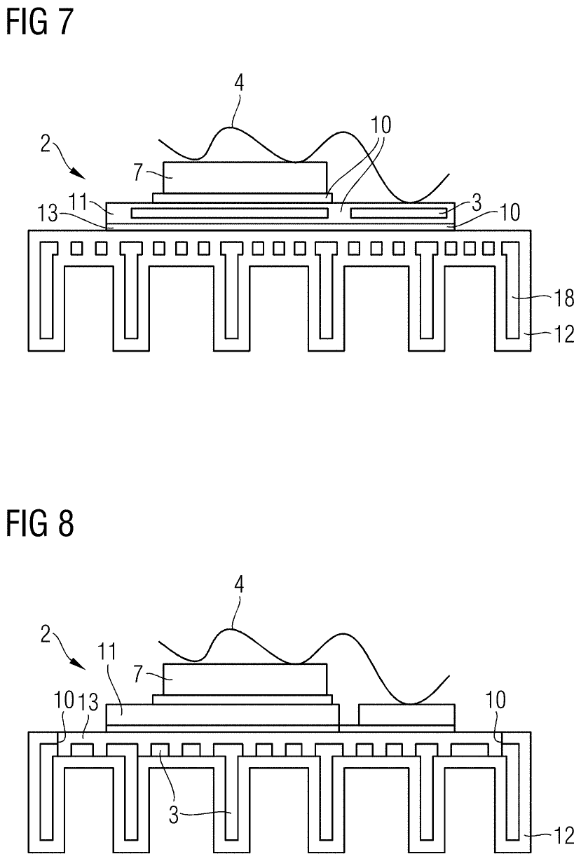

FIG. 7 depicts a sectional view that is similar to FIG. 6, but with a further heat pipe 18 formed additionally in the heat sink 12. The arrangement includes a heat emitting electrical/electronic component 7, which is mounted on a circuit carrier board 2. The component 7 is electrically connected to a bonding wire 4.

The heat pipe 3 is formed in the circuit carrier board 2. The heat pipe 3 may be formed in a ceramic substrate 13 or in an electrical circuit trace layer 11 of the circuit carrier board 2. Connecting layers 10 (e.g., thermally conductive pastes) connect the circuit carrier board 2 to the adjacent components.

FIG. 8 depicts a sectional view through a heat emitting electrical/electronic component 7, which is mounted on a circuit carrier board 2. The component 7 is electrically connected to a bonding wire 4.

The heat pipe 3 is formed in the ceramic substrate 13 of the circuit carrier board 2 and in the heat sink 12. The circuit carrier board also includes an electrical circuit trace layer 11. The heat pipe 3 may be a pulsating heat pipe. Connecting layers 10 (e.g., thermally conductive pastes) connect the circuit carrier board 2 to the adjacent components.

The particular feature of the embodiment is that the circuit carrier board 2, for instance the ceramic substrate 13, has, in the direction facing the heat sink 12, a partially open structure, and that the heat sink 12 has, in the direction facing the ceramic substrate 13, also a partially open, additional structure. Both structures are designed and joined so as to form the heat pipe 3. For this purpose, the ceramic substrate 13 is attached to the heat sink 12 in a sealed manner or inserted therein in a sealed manner.

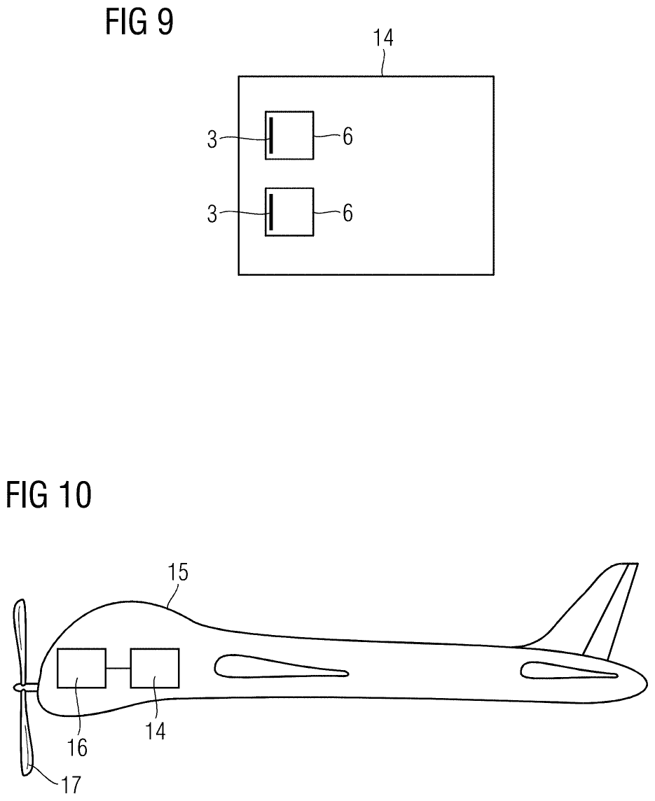

FIG. 9 depicts a block diagram of a converter 14 as an example of a power converter having an arrangement including a heat pipe 3 as shown in FIG. 2 to FIG. 8. The converter 14 includes a plurality of power modules 6, the heat from which is removed by the heat pipe 3.

FIG. 10 depicts an aircraft 15, for example an airplane, with an electric propulsion system. An electrical power source (not shown) supplies a converter 14, embodied as shown in FIG. 9. The converter 14 outputs electrical power to an electric motor 16, which in turn causes a propeller 17 to rotate.

To summarize, and in other words, the disclosure specifies, inter alia, the following embodiments.

A heat pipe is integrated in a substrate (e.g., circuit carrier board) of a power module in order to improve the removal of the waste heat in the power module by efficient heat spreading, and thereby to reduce the thermal resistance.

Because the diameter of the heat pipes is small and these do not need an internal vaporizer structure, integration in components, e.g. in a copper lead-frame, may be implemented easily. According to the disclosure, a channel structure may be introduced in the copper carrier for instance by milling, cold-forming, etching, spraying, or printing. This may be achieved by the copper carrier (e.g., lead-frame) including two pieces, which are soldered, for instance. On the top face of the copper carrier are soldered or sintered electrical components, (e.g., SiC-MOSFET, GaN, or IGBT). The channels of the heat pipe may be taken where the electrical components are located in order to provide rapid heat removal locally at the electrical power components.

For potential isolation purposes, the copper carrier is electrically isolated from the housing by electrically insulating layers. By heat spreading, the dissipated power density is reduced to such an extent that the additional heat removal may be arranged easily by air coolers or liquid coolers on the housing.

The heat pipe is partially filled with a cooling agent (e.g., water, R134a, or Novec) and then sealed to form a closed fluid circuit. This may be achieved by the copper carrier having a filling port, which is sealed by squeezing, for instance.

As a further embodiment, the ceramic of a DCB may contain a channel structure for the heat pipe. This may be achieved by the ceramic substrate including two parts, which are joined, with one of the carriers having a channel structure on the surface.

Although the disclosure has been described and illustrated more specifically in detail by the exemplary embodiments, the disclosure is not restricted by the disclosed examples and other variations may be derived therefrom by a person skilled in the art without departing from the scope of protection of the disclosure. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

### LIST OF REFERENCE SIGNS

1 power semiconductor
2 circuit carrier board
3 heat pipe
4 bonding wire
5 load current contact
6 power module
7 electrical/electronic component
8 housing
9 water
10 connecting layer (e.g. thermally conductive paste)
11 electrical circuit trace layer
12 heat sink
13 ceramic substrate
14 converter
15 aircraft
16 electric motor
17 propeller
18 further heat pipe
A region of low heat-spreading
B region of high heat-spreading
F flow direction of the water 9

1. An arrangement comprising:
a circuit carrier board;
at least one electrical/electronic component mounted on the circuit carrier board; and
at least one heat pipe formed in the circuit carrier board.

2. The arrangement of claim 1, wherein the heat pipe is arranged beneath the electrical/electronic component.

3. The arrangement claim 1, wherein the heat pipe is a pulsating heat pipe.

4. The arrangement of claim 1, wherein the electrical/electronic component is a power semiconductor.

5. The arrangement of claim 1, wherein the heat pipe has a meandering course or a concentrically wound course.

6. The arrangement of claim 1, wherein the heat pipe is formed in a ceramic substrate or in a circuit trace layer of the circuit carrier board.

7. The arrangement of claim 1, further comprising:
a metal heat sink arranged under the circuit carrier board and connected the circuit carrier board in a thermally conductive manner.

8. The arrangement of claim 7, further comprising:
an additional heat pipe formed in the metal heat sink.

9. The arrangement of claim 7, wherein the circuit carrier board has, in a direction facing the metal heat sink, a partially open structure,
wherein the metal heat sink has, in a direction facing the circuit carrier board, a partially open, additional structure, and
wherein both the partially open structure and the partially open, additional structure are designed and joined so as to form the heat pipe.

10. The arrangement of claim 1, wherein the circuit carrier board is a direct copper bonding substrate board.

11. A power converter comprising:
an arrangement having:
a circuit carrier board;
at least one electrical/electronic component mounted on the circuit carrier board; and
at least one heat pipe formed in the circuit carrier board.

12. The power converter of claim 11, wherein the power converter is a converter.

13. An aircraft comprising:
a converter having an arrangement comprising: circuit carrier board; at least one electrical/electronic component mounted on the circuit carrier board; and at least one heat pipe formed in the circuit carrier board; and
an electric motor for an electric aircraft propulsion system,
wherein the converter is configured to supply the electric motor with electrical power.

14. The aircraft of claim 13, wherein the aircraft is an airplane.

15. The aircraft of claim 14, further comprising:
a propeller configured to be driven by the electric motor.

16. The arrangement of claim 2, further comprising:
a metal heat sink arranged under the circuit carrier board and connected to the circuit carrier board in a thermally conductive manner.

17. The arrangement of claim 16, further comprising:
an additional heat pipe formed in the metal heat sink.

18. The arrangement of claim 16, wherein the circuit carrier board has, in a direction facing the metal heat sink, a partially open structure,
wherein the metal heat sink has, in a direction facing the circuit carrier board, a partially open, additional structure, and
wherein both the partially open structure and the partially open, additional structure are designed and joined so as to form the heat pipe.
